(19) United States
(12) Patent Application Publication
(10) Pub. No.: US 2021/0289624 A1
(43) Pub. Date: Sep. 16, 2021

(54) MODULE AND METHOD OF MANUFACTURING THE SAME

(71) Applicant: Murata Manufacturing Co., Ltd., Nagaokakyo-shi (JP)

(72) Inventor: Yosuke MINO, Nagaokakyo-shi (JP)

(21) Appl. No.: 17/336,470

(22) Filed: Jun. 2, 2021

Related U.S. Application Data
(63) Continuation of application No. PCT/JP2019/046180, filed on Nov. 26, 2019.

(30) Foreign Application Priority Data
Dec. 6, 2018 (JP) 2018-229177

(51) Int. Cl. H05K 1/11; H05K 1/18; H05K 1/09; H05K 3/24; H05K 3/34

(52) U.S. Cl. CPC H05K 1/111; H05K 1/181; H05K 1/09; H05K 2201/0347; H05K 3/3431; H05K 2201/09727; H05K 2201/099; H05K 3/243

(57) ABSTRACT

A module includes a ceramic multilayer substrate including a main surface; a surface-layer conductor pattern arranged on the main surface and integrally formed to include a land portion and an interconnection portion extending from the land portion; a first layer arranged to cover the land portion while exposing at least a part of the interconnection portion, the first layer having conductivity, the first layer being composed of a material that is lower in affinity to solder than a material for the surface-layer conductor pattern, and a component mounted on the first layer with solder being interposed. The solder is not in direct contact with the surface-layer conductor pattern.

### CROSS REFERENCE TO RELATED APPLICATION

This is a continuation of International Application No. PCT/JP2019/046180 filed on Nov. 26, 2019 which claims priority from Japanese Patent Application No. 2018-229177 filed on Dec. 6, 2018. The contents of these applications are incorporated herein by reference in their entireties.

### DISCLOSURE

### Technical Field

The present disclosure relates to a module and a method of manufacturing the same.

### Background Art

WO2006/027888 (PTL 1) describes obtaining a ceramic multilayer substrate by layering ceramic green sheets each having an interconnection pattern layer formed thereon and performing such treatment as press-bonding, binder removal treatment, firing, and the like. PTL 1 describes forming a film of Ni/Sn or Ni/Au on an electrode on the ceramic multilayer substrate with wet plating.

### SUMMARY OF DISCLOSURE

### Technical Problem

A land electrode and an interconnection for connecting land electrodes may be provided as an electrode on a ceramic multilayer substrate. Similar to the land electrode, the interconnection may also be provided on an outer surface. In this case, the land electrode and the interconnection can be formed from an integrated conductor pattern. A component is normally mounted on a land electrode with solder being interposed. Since a heating step is performed for reflow after the component is placed with solder being interposed, solder becomes fluid. In an example in which the land electrode and the interconnection are integrally formed on the outer surface of the ceramic multilayer substrate, a phenomenon may occur wherein fluid solder comes in contact with a material for the interconnection and is alloyed therewith, which results in flow of solder away from a position where it should properly be located.

When solder flows away, a component to be mounted may disadvantageously be displaced from a proper position due to flow of solder. In addition, “solder dissolution” may occur wherein a material for an interconnection is taken away due to alloying of solder with the material for the interconnection.

An object of the present disclosure is to provide a module in which solder is prevented from coming in contact with a material for an interconnection and being alloyed therewith at the time of mounting a component.

### Solution to Problem

In order to achieve the object, a module based on the present disclosure includes a ceramic multilayer substrate including a main surface; a surface-layer conductor pattern arranged on the main surface and integrally formed to include a land portion and an interconnection portion extending from the land portion; a first layer arranged to cover the land portion while exposing at least a part of the interconnection portion, the first layer having conductivity, the first layer being composed of a material that is lower in affinity to solder than a material for the surface-layer conductor pattern; and a component mounted on the first layer with the solder being interposed. The solder is not in direct contact with the surface-layer conductor pattern.

### Advantageous Effects

Since solder is not in direct contact with the surface-layer conductor pattern, solder can be prevented from flowing to the interconnection portion at the time of mounting the component. Therefore, a module in which solder is prevented from coming in contact with a material for an interconnection and being alloyed therewith can be realized.

### BRIEF DESCRIPTION OF DRAWINGS

FIG. 1 is a schematic plan view of a module;

FIG. 2 is a cross-sectional view along the line II-II in FIG. 1;

FIG. 3 is a partially enlarged view of a Z portion in FIG. 2;

FIG. 4 is a partially enlarged view of a modification of the module in FIG. 1;

FIG. 5 is a flowchart of a method of manufacturing the module.

FIG. 6 is a side view of a first step in the method of manufacturing a module in the second embodiment;

FIG. 7 is a plan view of the first step illustrated in FIG. 6;

FIG. 8 is a side view of a second step in the method of manufacturing the module;

FIG. 9 is a plan view of the second step illustrated in FIG. 8;

FIG. 10 is a cross-sectional view along the line X-X in FIG. 9;

FIG. 11 is a side view of a third step in the method of manufacturing the module;

FIG. 12 is a side view of a fourth step in the method of manufacturing the module;

FIG. 13 is a side view of a fifth step in the method of manufacturing the module;

FIG. 14 is a plan view of the fifth step illustrated in FIG. 13.

FIG. 15 is a side view of a sixth step in the method of manufacturing the module;

FIG. 16 is a side view of a seventh step in the method of manufacturing the module;

FIG. 17 is a side view of an eighth step in the method of manufacturing the module;

FIG. 18 shows a first modification of a surface-layer conductor pattern included in the module;

FIG. 19 shows a second modification of the surface-layer conductor pattern included in the module;

FIG. 20 shows a third modification of the surface-layer conductor pattern included in the module; and

FIG. 21 shows a fourth modification of the surface-layer conductor pattern included in the module.

### DETAILED DESCRIPTION

A dimensional ratio shown in the drawings does not necessarily faithfully represent an actual dimensional ratio and a dimensional ratio may be exaggerated for the sake of convenience of description. The terms up or upper or down or lower mentioned in the description below do not mean absolute up or upper or down or lower but may mean relative up or upper or down or lower in terms of a shown position.

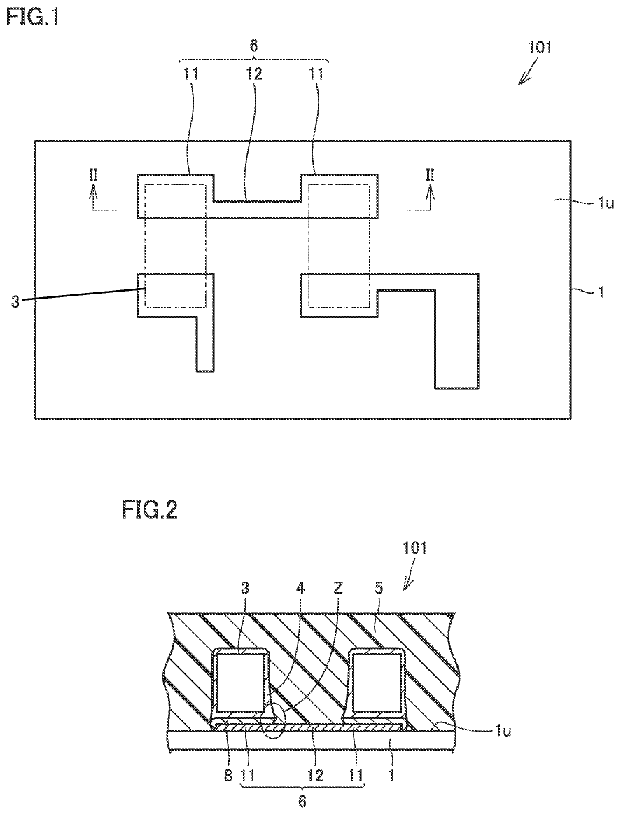

A module 101 will be described with reference to FIGS. 1 to 4. FIG. 1 shows a schematic plan view of the module 101. For the sake of convenience of description, FIG. 1 shows the module 101 from which a molding resin, a component, solder, and the like basically included therein have been removed. FIG. 1 virtually shows a component 3 with a chain double-dotted line. FIG. 2 shows a cross-sectional view along the line II-II in FIG. 1 in which the component 3 is mounted with solder 4 being interposed and sealed with a molding resin 5.

The module 101 includes a ceramic multilayer substrate 1 including a main surface 1u; a surface-layer conductor pattern 6 arranged on the main surface 1u and integrally formed to include a land portion 11 and an interconnection portion 12 extending from the land portion 11; a first layer 8; and a component 3. The first layer 8 is arranged to cover the land portion 11 while exposing at least a part of the interconnection portion 12. The first layer 8 has conductivity and includes a material that is lower in affinity (i.e., attraction) to the solder 4 than a material for the surface-layer conductor pattern 6. In other words, the material for the first layer 8 is relatively lower in affinity to the solder 4, while the material for the surface-layer conductor pattern 6 is relatively higher in affinity to the solder 4.

The component 3 is mounted with the solder 4 being interposed so as to electrically be connected to the first layer 8. The solder 4 is not in direct contact with the surface-layer conductor pattern 6. The component 3 “being mounted on the first layer 8 with the solder 4 being interposed” means a construction in which only the solder 4 is present between the component 3 and the first layer 8. Without being limited as such, a layer composed of a material other than the solder 4 may be interposed.

Though a ceramic multilayer substrate is employed as the substrate in the present embodiment, a single-layer substrate instead of the multilayer substrate may be employed. The substrate may be a resin substrate. When the resin substrate is employed, it may be a multilayer substrate or a single-layer substrate.

The surface-layer conductor pattern 6 is, for example, mainly composed of copper. The surface-layer conductor pattern 6 is in a two-dimensional shape, for example, as shown in FIG. 1. In FIG. 1, three surface-layer conductor patterns are arranged on the main surface 1u. Description is continued below with attention being paid to one of the surface-layer conductor patterns (i.e., pattern 6). In the example shown here, two land portions 11 are connected to each other through one interconnection portion 12. The land portion 11 is a portion for electrical connection on which the component 3 is placed. The interconnection portion 12 is a portion for electrical connection in a direction in parallel to the main surface 1u. The first layer 8 can be mainly composed of, for example, nickel. As used herein, an object that is “mainly composed” of a material (e.g., copper or nickel) means that the material occupies at least half of the object in terms of a weight ratio. The first layer 8 is a film formed by plating

The component 3 is sealed with the molding resin 5, which is formed to cover the main surface 1u. Though FIG. 1 shows an example in which two components 3 identical in size are mounted on main surface 1u, the number, size, orientation, and positional relation of components mounted here are shown merely by way of example and the components are not necessarily as illustrated.

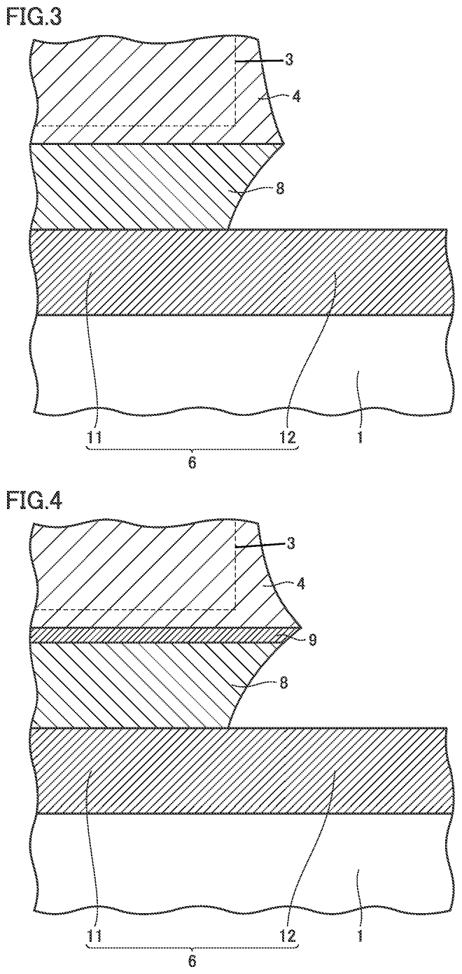

FIG. 3 shows a Z portion in FIG. 2 as being enlarged. As shown in FIG. 3, the solder 4 may be located directly on the first layer 8. However, a second layer 9 (see FIG. 4) composed of a material high in affinity to the solder 4 may be provided in advance on an upper surface of the first layer 8 for easier application of the solder 4 to the first layer 8. The second layer 9 is expected to substantially disappear because it will form an alloy with the solder 4 when the solder 4 is applied and heated for mounting the component 3. However, as shown in FIG. 4, the second layer 9 may remain between the first layer 8 and solder 4.

In the present embodiment, the first layer 8 is arranged to cover the land portion 11 of the surface-layer conductor pattern 6, and the solder 4 is not in direct contact with the surface-layer conductor pattern 6. Therefore, the solder 4 can be prevented from flowing to the interconnection portion 12 when mounting the component 3, and displacement of the component 3 can be suppressed. In addition, contact of the solder 4 with the material for the interconnection portion 12 and resultant alloying thereof can be avoided.

The solder 4 is preferably not in direct contact with the surface-layer conductor pattern 6 around the entire perimeter of the land portion 11. Preferably, around the perimeter of the land portion 11, the solder 4 is not in direct contact with the surface-layer conductor pattern 6, in particular on a side where the interconnection portion 12 extends.

As shown in the present embodiment, preferably, the molding resin 5 with which at least the component 3 is sealed is provided. Along the interconnection portion 12, the molding resin 5 covers the surface-layer conductor pattern 6 and is in direct contact with the surface-layer conductor pattern 6.

As shown in the present embodiment, preferably, the surface-layer conductor pattern 6 is mainly composed of copper. By adopting this construction, a surface interconnection low in electrical resistance value can be realized.

As shown in the present embodiment, the first layer 8 is preferably mainly composed of nickel. By adopting this construction, the solder 4 can be prevented from flowing to a portion where copper is exposed.

The first layer 8 has a lower end in contact with the land portion 11 and an upper end in contact with the solder 4. Preferably, the upper end projects toward interconnection portion 12 relative to the lower end. By adopting this construction, the solder 4 can efficiently be prevented from flowing away to the interconnection portion 12. FIG. 3 shows an example in which, the upper end of the first layer 8 projects toward the interconnection portion 12 relative to the lower end of the first layer 8.

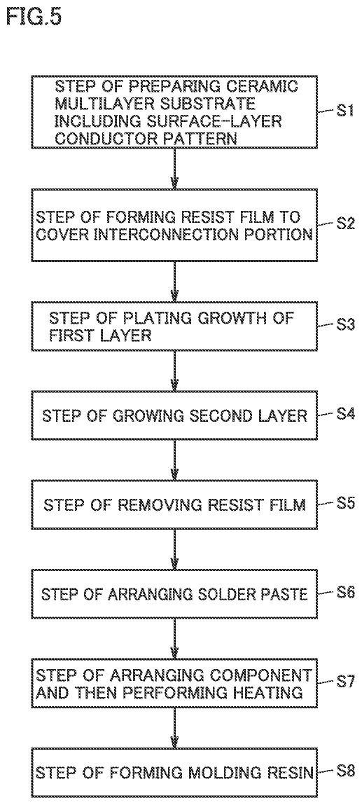

A method of manufacturing the module 101 will be described with reference to FIGS. 5 to 17 and 2. FIG. 5 shows a flowchart of the method of manufacturing the module 101.

The method of manufacturing the module 101 includes a step S1 of preparing a substrate including a surface-layer conductor pattern integrally formed to include a land portion and an interconnection portion extending from the land portion on a main surface which is an outermost surface, a step S2 of forming a resist film to cover the interconnection portion without covering the land portion, a step S3 of plating growth of a first layer including a material that is lower in affinity to solder than a material for the surface-layer conductor pattern on a surface of the land portion, a step S4 of growing a second layer including a material that is higher in affinity to solder than the material for the first layer on a surface of the first layer, a step S5 of removing the resist film, a step S6 of arranging a solder paste on the second layer, and a step S7 of placing a component on the solder paste and then performing heating. In the example shown here, the method further includes a step S8 of forming a molding resin to seal at least the component. Each step will be described in further detail below with reference to the drawings.

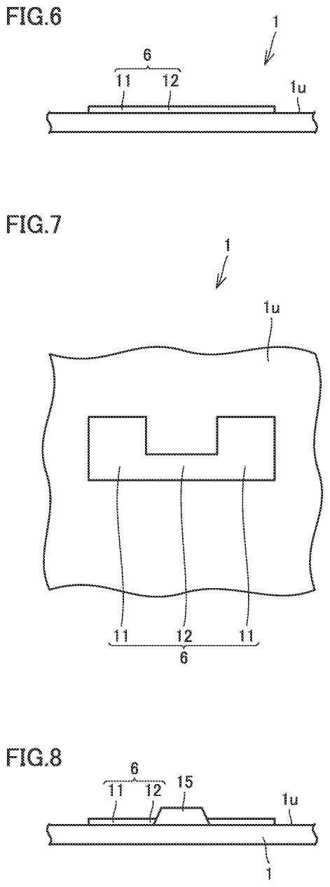

Initially, in the step S1, as shown in FIG. 6, a ceramic multilayer substrate 1 is prepared as the “substrate”. FIG. 7 shows a plan view of the ceramic multilayer substrate 1 in this state. The ceramic multilayer substrate 1 includes the main surface 1u as the outermost surface. The surface-layer conductor pattern 6 is formed on the main surface 1u. The surface-layer conductor pattern 6 can be formed by printing. The surface-layer conductor pattern 6 includes the land portion 11 and the interconnection portion 12. The interconnection portion 12 extends from the land portion 11. The ceramic multilayer substrate 1 is obtained by printing surface-layer conductor pattern 6 on an outermost layer of a plurality of layered ceramic green sheets and thereafter firing the ceramic green sheets. The ceramic multilayer substrate 1 may contain a conductor pattern in the inside.

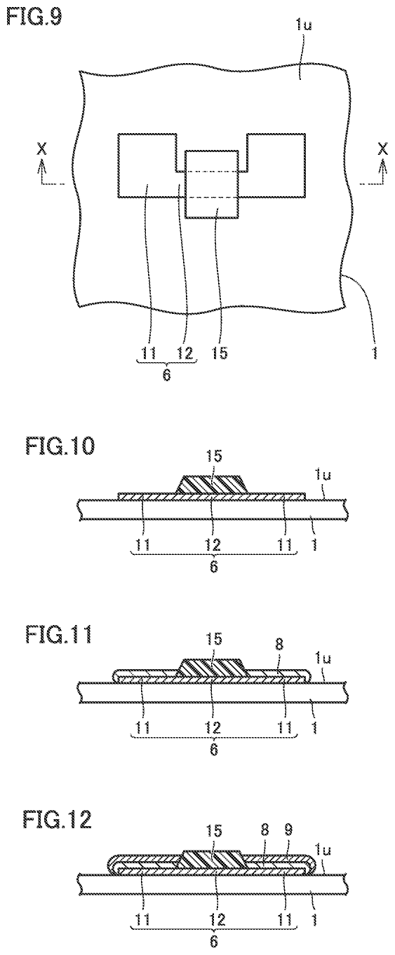

Then, in step S2, a resist film 15 is formed as shown in FIG. 8. The resist film 15 covers the interconnection portion 12 without covering the land portion 11. FIG. 9 shows a plan view in this state. FIG. 10 shows a cross-sectional view along the line X-X in FIG. 9. The entire interconnection portion 12 does not necessarily have to be covered with the resist film 15. In other words, a part of the interconnection portion 12 does not have to be covered with the resist film 15.

A central portion of interconnection portion 12 is covered with the resist film 15. A portion of the interconnection portion 12 connected to the land portion 11 on the left in FIGS. 8-10 and a portion thereof connected to land portion 11 on the right in FIGS. 8-10 are spaced apart from each other by a region covered with resist film 15. In other words, from the land portion 11 on the left to the land portion 11 on the right along the surface-layer conductor pattern 6, the region covered with the resist film 15 should be passed through at least once. The resist film 15 may be formed by screen printing or by an ink-jet method.

In step S3, as shown in FIG. 11, plating growth of the first layer 8 on the surface of the land portion 11 is carried out. The first layer 8 is composed of a material lower in affinity to solder than the material for surface-layer conductor pattern 6. For example, the first layer 8 may be composed of nickel. Therefore, plating growth of the nickel is carried out. When a side surface of the land portion 11 is exposed, the first layer 8 may be formed to cover also the side surface.

In step S4, as shown in FIG. 12, the second layer 9 is grown on the surface of the first layer 8. The second layer 9 is composed of a material higher in affinity to solder than the material for the first layer 8. In other words, the material for the first layer 8 is relatively lower in affinity to solder, while the material for the second layer 9 is relatively higher in affinity to solder. The second layer 9 may be composed, for example, of gold. In growing the second layer 9, for example, a film of gold should only be formed by sputtering. Though FIG. 12 shows the first layer 8 and second layer 9 equal to each other in thickness for the sake of convenience of illustration, the second layer 9 may actually be smaller in thickness than the first layer 8.

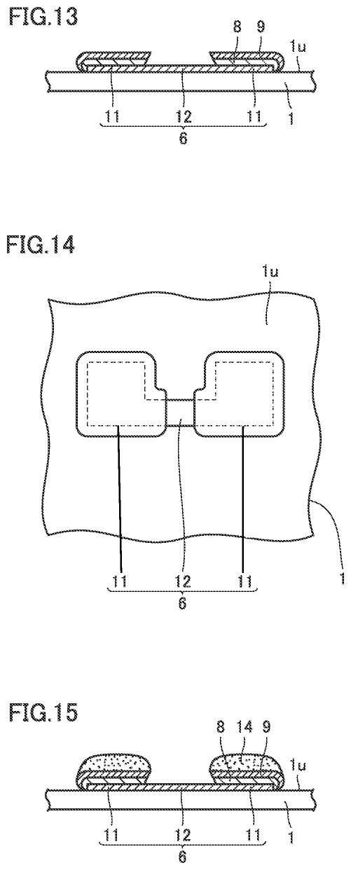

In step S5, the resist film 15 is removed. The resist film 15 can be removed by a strong alkali solution. For example, an NaOH solution may be adopted as the strong alkali solution. By performing step S5, a structure shown in FIG. 13 is obtained. FIG. 14 shows a plan view in this state. At least a part of the interconnection portion 12 in the surface-layer conductor pattern 6 is exposed. In a portion other than that, the surface of the surface-layer conductor pattern 6 is covered with the first layer 8 and second layer 9. On a side surface of the land portion 11 on a side of the interconnection portion 12, the first layer 8 is exposed. On the side surface of the land portion 11 on the side of the interconnection portion 12, the second layer 9 is spaced from surface-layer conductor pattern 6.

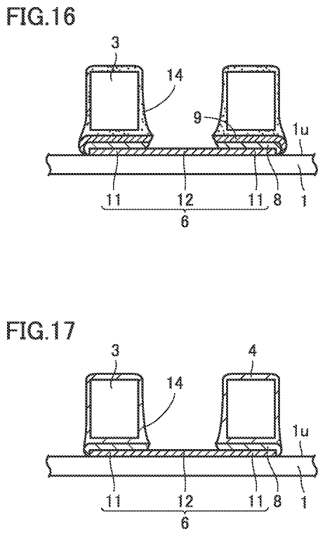

In step S6, as shown in FIG. 15, a solder paste 14 is arranged on second layer 9. In step S7, the component 3 is arranged on the solder paste 14 and thereafter heating is performed. This heating is performed for reflow. Heating, for example, to approximately 260° C. may be performed. As a result of heating, the solder paste 14 becomes fluid, and an electrode of the component 3 is covered with solder as shown in FIG. 16. Though FIG. 16 shows the second layer 9 as being present, actually, the second layer 9 substantially disappears because the material for the second layer 9 forms an alloy with solder and the second layer 9 is dissolved into solder. When the second layer 9 is composed of gold, properly speaking, solder is an alloy of solder and gold. As the temperature thereafter lowers to a room temperature, solder is solidified and a structure in which the component 3 is mounted with the solder 4 being interposed is obtained as shown in FIG. 17. Since the second layer 9 has already substantially disappeared in FIG. 17, the second layer 9 is not drawn between the first layer 8 and the solder 4.

In step S8, the molding resin 5 is formed to seal at least the component 3. The module 101 shown in FIG. 2 is thus obtained. Though a structure corresponding in size to a single module is shown and illustrated with reference to FIGS. 6 to 17 and 2, this is merely for the convenience of illustration. Actually, a method of obtaining a plurality of modules by simultaneously manufacturing structures for a plurality of modules in parallel in a state of a substrate assembly and thereafter cutting the substrate assembly into individual substrates having an individual size may be adopted. The step S8 is not essential. If the molding resin 5 is not required for completing the module, the step S8 does not have to be performed.

In the present embodiment, the resist film 15 is formed in step S2, and thereafter steps S3 and S4 are performed to form the first layer 8 and second layer 9. Thereafter, the resist film 15 is removed in step S5. Therefore, the second layer 9 can be spaced apart from the interconnection portion 12. Thereafter, the component 3 is mounted by performing steps S6 and S7. Therefore, the module 101 can be manufactured while solder is not in direct contact with the interconnection portion 12. The module in which solder is prevented from coming in contact with the material for the interconnection portion 12 and being alloyed therewith can thus be obtained.

The step S2 of forming the resist film 15 is preferably performed by the ink-jet method. By adopting this method, the resist film 15 can be formed in a desired region with high precision.

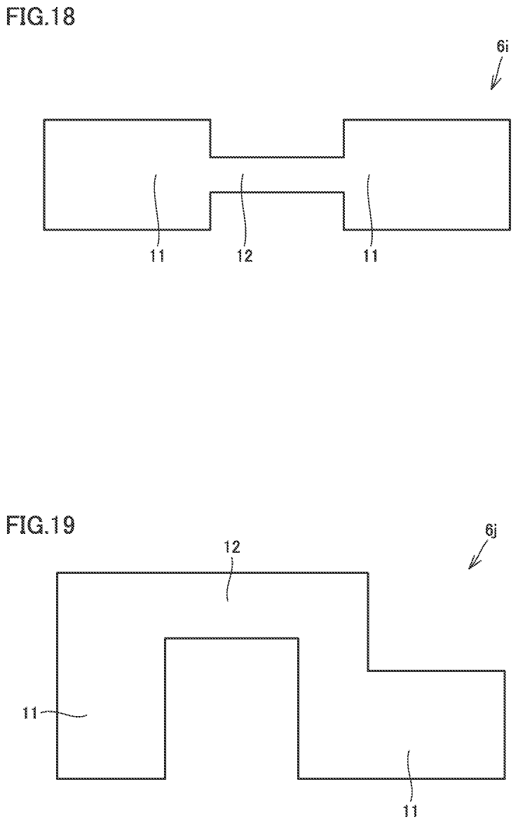

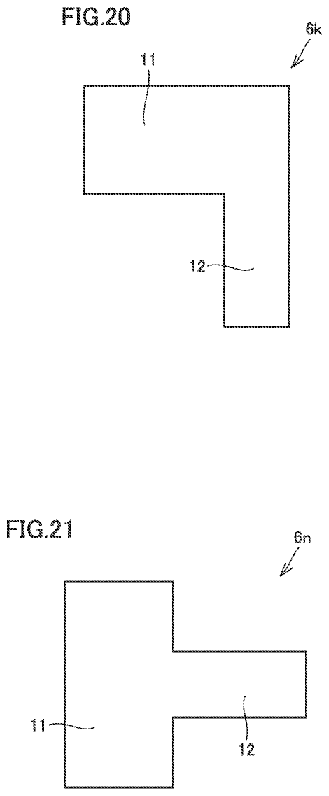

Although the surface-layer conductor pattern 6 as shown in FIG. 1 is embodiment-shaped, the shape of the surface-layer conductor pattern 6 is not limited thereto and the surface-layer conductor pattern 6 may be in another shape. For example, the surface-layer conductor pattern 6 may be in an H shape like a surface-layer conductor pattern 6i shown in FIG. 18. The surface-layer conductor pattern 6 may be in a hook shape like a surface-layer conductor pattern 6j shown in FIG. 19. The surface-layer conductor pattern 6j in which two land portions 11 are arranged in directions different from each other may be applicable. The two land portions 11 are not necessarily arranged in parallel. The land portions 11 are not necessarily present at respective opposing ends of interconnection portion 12. For example, the surface-layer conductor pattern 6 may be in an L shape like a surface-layer conductor pattern 6k shown in FIG. 20. The surface-layer conductor pattern 6 may be in a T-shape in which the interconnection portion 12 extends from a central portion of a side of a land electrode like a surface-layer conductor pattern 6n shown in FIG. 21.

Some features in embodiments above may be adopted as being combined as appropriate.

It should be understood that the embodiments disclosed herein are illustrative and non-restrictive in every respect. The scope of the present disclosure is defined by the terms of the claims and is intended to include any modifications within the scope and meaning equivalent to the terms of the claims.

1. A module comprising:
a substrate including a main surface;
a surface-layer conductor pattern arranged on the main surface and integrally formed to include a land portion and an interconnection portion extending from the land portion;
a first layer arranged to cover the land portion while exposing at least a part of the interconnection portion, the first layer having conductivity, the first layer including a material that is lower in affinity to solder than a material for the surface-layer conductor pattern; and
a component mounted on the first layer with the solder being interposed, wherein
the solder is not in direct contact with the surface-layer conductor pattern.

2. The module according to claim 1, comprising a molding resin that seals at least the component, wherein
the molding resin covers and is in direct contact with the interconnection portion of the surface-layer conductor pattern.

3. The module according to claim 1, wherein
the surface-layer conductor pattern is mainly composed of copper.

4. The module according to claim 3, wherein
the first layer is mainly composed of nickel.

5. The module according to claim 1, wherein
the first layer is mainly composed of nickel.

6. The module according to claim 1, wherein
the first layer has a lower end in contact with the land portion and an upper end in contact with the solder, and the upper end projects toward the interconnection portion relative to the lower end.

7. A method of manufacturing a module comprising:
preparing a surface-layer conductor pattern on a main surface of a substrate, the main surface being an outermost surface of the substrate, the surface-layer conductor pattern being integrally formed to include a land portion and an interconnection portion extending from the land portion;
forming a resist film to cover the interconnection portion without covering the land portion;
plating growth of a first layer on a surface of the land portion, the first layer including a material that is lower in affinity to solder than a material for the surface-layer conductor pattern;
growing a second layer on a surface of the first layer, the second layer including a material that is higher in affinity to solder than the material for the first layer;
removing the resist film;
arranging a solder paste on the second layer; and
placing a component on the solder paste and then performing heating.

8. The method according to claim 7, wherein
the resist film is formed by an ink jet method.

9. The method according to claim 7, wherein
the surface-layer conductor pattern is mainly composed of copper.

10. The method according to claim 9, wherein
the first layer is mainly composed of nickel.

11. The method according to claim 7, wherein
the first layer is mainly composed of nickel.
